(19) United States
(12) Patent Application Publication
(10) Pub. No.: US 2008/0277704 A1
(43) Pub. Date: Nov. 13, 2008

(54) SEMICONDUCTOR DEVICE AND MANUFACTURING METHOD THEREOF

(75) Inventor: Hiroyuki KANAYA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/110,601

(22) Filed: Apr. 28, 2008

(30) Foreign Application Priority Data
May 11, 2007 (JP) 2007-126446

(51) Int. Cl. H01L 27/115; H01L 21/02

(52) U.S. Cl. 257/295; 438/3; 257/E27.104; 257/E21.664; 257/E21.009

(57) ABSTRACT

This disclosure concerns a semiconductor device comprising a switching transistor provided on a semiconductor substrate; an interlayer dielectric film formed on the switching transistor; a ferroelectric capacitor including an upper electrode, a ferroelectric film, and a lower electrode formed on the interlayer dielectric film; a contact plug provided within the interlayer dielectric film and electrically connected to the lower electrode; a diffusion layer connected to between the contact plug and the switching transistor; a barrier metal covering a whole upper surface of the upper electrode; and an insulation sidewall film provided on a side surface of the barrier metal and provided substantially on a same plane as a side surface of the upper electrode.

### CROSS-REFERENCE TO RELATED APPLICATION

This application is based upon and claims the benefit of priority from the prior Japanese Patent Application No. 2007-126446, filed on May 11, 2007, the entire contents of which are incorporated herein by reference.

### BACKGROUND OF THE INVENTION

1. Field of the Invention

The present invention relates to a semiconductor device and a manufacturing method thereof, and relates to a ferroelectric memory and a manufacturing method thereof, for example.

2. Related Art

Along miniaturization of a ferroelectric memory device, damage to a ferroelectric capacitor becomes remarkable. As one of reasons for this, there is an influence of hydrogen entering a contact portion of an upper electrode. There is a process of embedding tungsten into a contact hole formed on the upper electrode, for example. The deposition process of tungsten is performed in the atmosphere containing a large amount of hydrogen. Therefore, hydrogen is diffused into a ferroelectric material via a contact hole, and degrades the ferroelectric material.

To solve this problem, there is considered a method of providing a barrier metal to block hydrogen, on the upper electrode via the contact hole. According to this method, barrier metal is provided before depositing tungsten, after forming the contact hole. However, according to this method, because the barrier metal is deposited via the contact hole, coverage of the barrier metal on the upper electrode is poor. Therefore, according to this method, barrier metal cannot securely shield hydrogen.

### SUMMARY OF THE INVENTION

A semiconductor device according to an embodiment of the present invention comprises a switching transistor provided on a semiconductor substrate; an interlayer dielectric film formed on the switching transistor; a ferroelectric capacitor including an upper electrode, a ferroelectric film, and a lower electrode formed on the interlayer dielectric film; a contact plug provided within the interlayer dielectric film and electrically connected to the lower electrode; a diffusion layer connected to between the contact plug and the switching transistor; a barrier metal covering a whole upper surface of the upper electrode; and an insulation sidewall film provided on a side surface of the barrier metal and provided substantially on a same plane as a side surface of the upper electrode.

A manufacturing method of a semiconductor device including a ferroelectric capacitor including an upper electrode, a ferroelectric film, and a lower electrode according to an embodiment of the present invention, the manufacturing method comprises forming a switching transistor on a semiconductor substrate and a diffusion layer connected to the switching transistor; forming an interlayer dielectric film on the switching transistor; forming a contact plug connected to the diffusion layer within the interlayer dielectric film; depositing a lower electrode material, a ferroelectric film material, and an upper electrode material on the contact plug; depositing a barrier metal on the upper electrode; depositing a mask material on the barrier metal; processing the mask material into a pattern of the ferroelectric capacitor; etching the barrier metal using the mask material as a mask; forming an insulation sidewall film on a side surface of the barrier metal; and etching the upper electrode material, the ferroelectric film material, and the lower electrode material by using the mask material and the insulation sidewall film as a mask to form the upper electrode, the ferroelectric film and the lower electrode.

### BRIEF DESCRIPTION OF THE DRAWINGS

FIG. 1 to FIG. 6 are cross-sectional views showing a manufacturing method of a ferroelectric memory according to a first embodiment of the present invention;

FIG. 7 is a cross-sectional view showing one example of the ferroelectric memory according to the first embodiment;

FIGS. 8 and 9 are cross-sectional views showing a manufacturing method of a ferroelectric memory according to a second embodiment of the present invention;

FIGS. 10 and 11 are cross-sectional views showing a manufacturing method of a ferroelectric memory according to a third embodiment of the present invention;

FIGS. 12 and 13 are cross-sectional views showing a manufacturing method of a ferroelectric memory according to a fourth embodiment of the present invention;

FIGS. 14 and 15 are cross-sectional views showing a manufacturing method of a ferroelectric memory according to a fifth embodiment of the present invention; and

FIG. 16 to FIG. 18 are cross-sectional views showing a manufacturing method of a ferroelectric memory according to a sixth embodiment of the present invention.

### DETAILED DESCRIPTION OF THE INVENTION

Embodiments of the present invention will be explained below in detail with reference to the accompanying drawings. Note that the invention is not limited thereto.

### First Embodiment

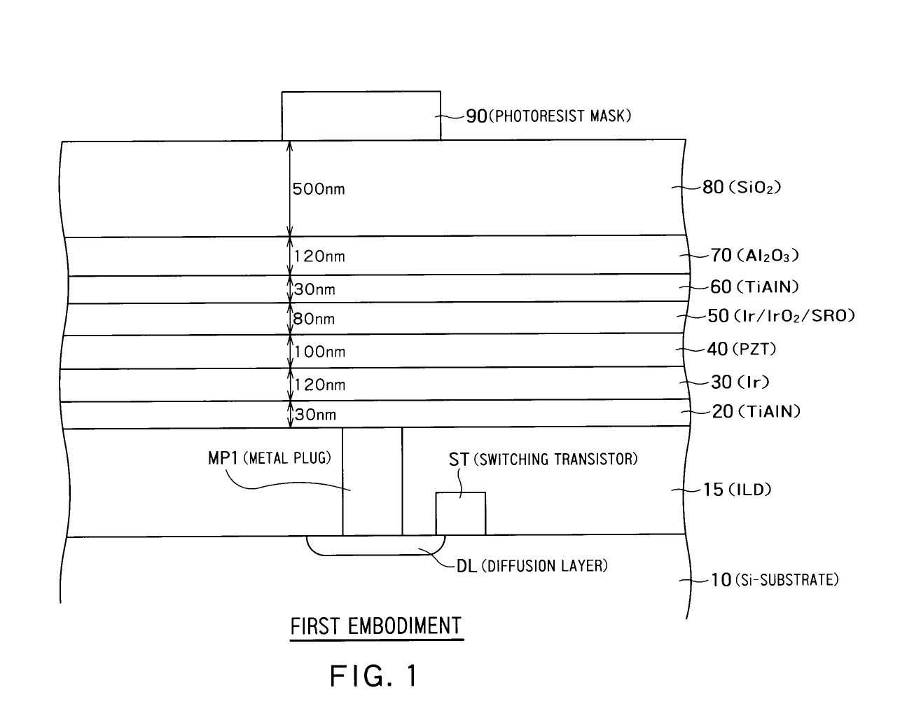

FIG. 1 to FIG. 6 are cross-sectional views showing a manufacturing method of a ferroelectric memory according to a first embodiment of the present invention. First, a switching transistor ST is formed on a silicon substrate 10, using a conventional process. The switching transistor ST can be similar to a conventional one, and therefore, its detailed description is omitted. In a formation process of the switching transistor ST, a diffusion layer DL is formed as a source layer or a drain layer of the switching transistor ST. Next, an interlayer dielectric film 15 is deposited on the switching transistor ST. The interlayer dielectric film 15 is a low-k film having a smaller specific dielectric constant than that of a silicon oxide film. Next, a contact hole reaching the diffusion layer DL is formed, and metal is filled into the contact hole. Thereafter, to flatten the surface, the metal is ground to the upper surface of the interlayer dielectric film 15 by using CMP (Chemical Mechanical Polishing). As a result, a metal plug MP1 as a contact plug is formed. The metal plug MP1 includes tungsten, for example.

Next, a barrier metal 20, a lower electrode material 30, a ferroelectric material 40, and an upper electrode material 50 are deposited sequentially on the interlayer dielectric film 15 containing the metal plug MP1. The barrier metal 20 includes a single layer film of titan nitride (T₃N₄, etc.), titan aluminum nitride (TiAlN, etc.), tungsten nitride (WN, etc.) or titanium (Ti), or a laminated film of these materials. In the present embodiment, the barrier metal 20 includes a single layer film of TiAlN. The barrier metal 20 has a film thickness of 30 nm, for example.

The lower electrode material 30 includes a single layer film of Ir, oxide iridium (IrO₂, IrOₓ), Pt, SrRuO₃, LaSrO₃, and SrRuO₃ (hereinafter, also called SRO), or a laminated film of these materials, for example. In the present embodiment, the lower electrode material 30 includes a single layer film of iridium. The lower electrode material 30 has a film thickness of 120 nm, for example.

The ferroelectric material 40 includes PZT (Pb (ZrₓTi₍₁₋ₓ₎O₃), SBT (SrₓBi_{y}Ta_{z}Oₐ), BLT (BiₓLa_{y}O_{z}), for example, where x, y, z, a are positive numbers. In the present embodiment, the ferroelectric material 40 includes PZT. The ferroelectric material 40 has a film thickness of 100 nm, for example.

The upper electrode material 50 includes a single layer film of Ir, oxide iridium (IrO₂, IrOₓ), Pt, SrRuO₃, LaSrO₃ or SrRuO₃ (hereinafter, also called SRO), or a laminated film of these materials, for example. In the present embodiment, the upper electrode material 50 includes a laminated film of Ir, IrO₂, and SRO. In the drawing, the upper electrode material 50 is expressed as a single layer. The Ir layer has a film thickness of 20 nm, for example. The IrO₂ layer has a film thickness of 50 nm, for example. The SRO film has a film thickness of 10 nm, for example.

Next, a barrier metal layer 60 is deposited on the upper electrode material 50. The barrier metal layer 60 is a metal film containing nitrogen, and includes a single layer film of titan aluminum nitride (TiAlN, etc.), titan nitride (Ti₃N₄, etc.), or tungsten nitride (WN, etc.), or a laminated film of two or more layers. The metal film containing nitride is excellent in a characteristic of shielding hydrogen, and is therefore suitable as a barrier metal layer. The barrier metal layer 60 has a film thickness of 30 nm, for example.

Next, an alumina (Al₂O₃) layer 70 and a silicon oxide film 80 as hard mask materials are deposited on the barrier metal layer 60. The alumina layer 70 has a film thickness of about 120 nm, for example. The silicon oxide film 80 has a film thickness of 500 nm, for example. A suitable mask material is a single layer film of aluminum oxide (Al₂O₃), zirconium oxide (ZrO₂, etc.), aluminum silicon oxide (AlSiₓO_{y}), silicon oxide (SiO₂), titan oxide (TiO₂), aluminum oxynitride (AlOₓN_{y}) or silicon nitride (Si₃N₄), or a laminated film of two or more layers of these materials. In the present embodiment, a laminated film of the alumina (Al₂O₃) layer 70 and the silicon oxide film 80 is employed.

Next, photoresist is coated onto the silicon oxide film 80, and this is patterned into a ferroelectric capacitor. A photoresist mask 90 covering a front surface region of the ferroelectric capacitor on the upper surface of the silicon oxide film 80 is formed. As a result, a cross-sectional configuration as shown in FIG. 1 is obtained.

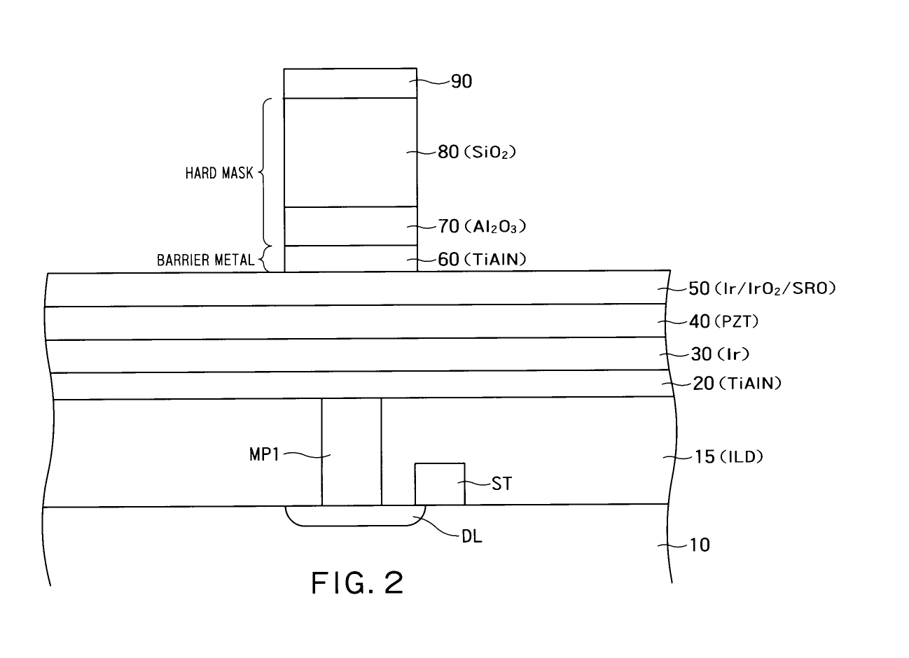

Next, as shown in FIG. 2, the silicon oxide film 80, the alumina layer 70, and the barrier metal layer 60 are etched by RIE (Reactive Ion Etching) by using the photoresist mask 90 as a mask. When it is difficult to process the barrier metal layer 60 by using the photoresist mask 90 as a mask, the barrier metal layer 60 can be processed by using the silicon oxide film 80 and the alumina layer 70 after the etching as a hard mask.

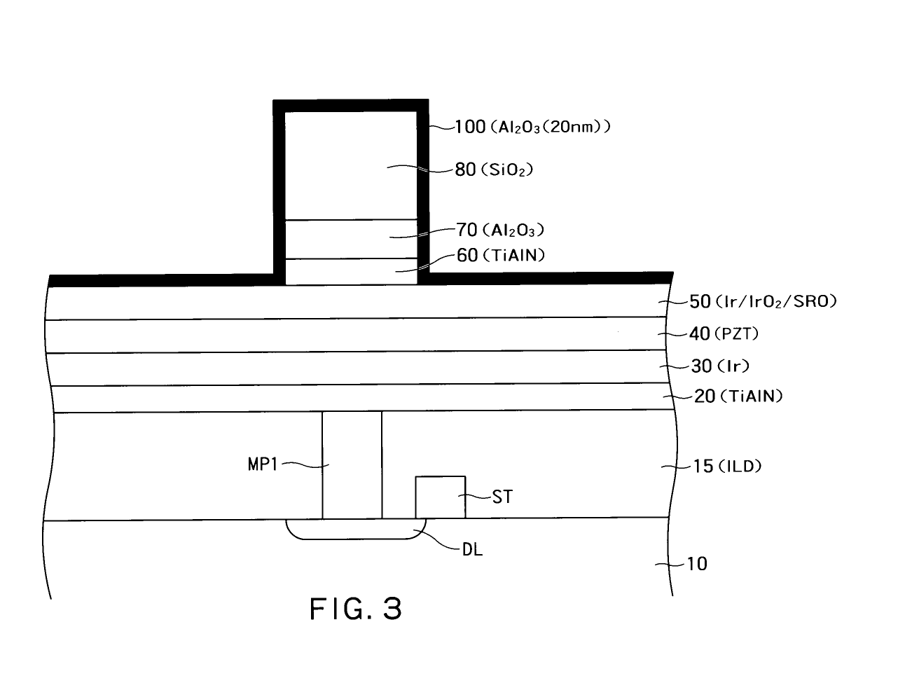

Next, as shown in FIG. 3, a side mask material 100 is deposited on the upper surface of the upper electrode material 50, on the side surface and the upper surface of the silicon oxide film 80, on the side surface of the alumina layer 70, and on the side surface of the barrier metal layer 60. The side mask material 100 is an insulation film shielding a gas containing chlorine, and is preferably a single layer film of aluminum oxide (Al₂O₃, etc.), zirconium oxide (ZrO₂, etc.), aluminum silicon oxide (AlSiₓO_{y}, etc.), silicon oxide (SiO₂), titan oxide (TiO₂, etc.), silicon nitride (Si₃N₄, etc.), aluminum nitride (AlN) or aluminum oxynitride (AlOₓN_{y}), or a laminated film of two or more layers of these materials. This is because these materials are excellent in shielding of hydrogen. In the present embodiment, a single layer film of aluminum oxide (Al₂O₃) is employed as the side mask material 100. The side mask material 100 has a film thickness of 20 nm, for example. The side mask material 100 is deposited using ALD (Atomic Layer Deposition) or the like.

Next, the side mask material 100 is anisotropically etched back. Accordingly, the side mask material deposited on the upper surface of the silicon oxide film 80 and the upper surface of the upper electrode material 50 is removed, and the side mask material 100 is left on only the side surface of the silicon oxide film 80, on the side surface of the alumina layer 70, and on the side surface of the barrier metal layer 60. The processed side mask material 100 is hereinafter called the side mask 100.

After the side mask 100 is formed, the upper electrode material 50, the ferroelectric material 40, the lower electrode material 30, and the barrier metal layer 20 are anisotropically etched by using the silicon oxide film 80, the alumina layer 70 and the side mask 100 as a mask. As a result, the upper electrode material 50, the ferroelectric material 40, the lower electrode material 30, and the barrier metal layer 20 are processed in a pattern of the ferroelectric capacitor. The upper electrode material 50, the ferroelectric material 40, and the lower electrode material 30 after the processing are hereinafter called the upper electrode 50, the ferroelectric layer 40, and the lower electrode 30, respectively.

In this etching process, a gas containing BCl₃, Cl₂, O₂, Ar, CO, or N₂ is used as an etching gas. In other words, the upper electrode material 50, the ferroelectric material 40, the lower electrode material 30, and the barrier metal layer 20 are etched using the gas containing chlorine. However, in this case, because the side surface of the barrier metal layer 60 is covered by the side mask 100, the side surface of the barrier metal layer 60 is not etched (not side etched). As a result, the coverage of the barrier metal layer 60 on the upper surface of the upper electrode 50 is maintained satisfactorily.

Thereafter, an interlayer dielectric film 115 covering the whole ferroelectric capacitor FC is deposited. The interlayer dielectric film 115 includes a silicon oxide film, for example. Then, a contact hole is formed to reach the upper electrode 50, piercing through the interlayer dielectric film 115, the silicon oxide film 80, the alumina layer 70, and the barrier metal layer 60. Further, metal is filled into the contact hole, and this metal is ground up to the upper surface of the interlayer dielectric film 115 by CMP. As a result, a metal plug MP2 is formed. A material of the metal plug MP2 is tungsten, for example.

Tungsten is deposited in the atmosphere containing a large amount of hydrogen, as described above. If the barrier metal layer 60 is side etched, hydrogen relatively easily reaches the ferroelectric film 40 via the interlayer dielectric film 115 from the contact hole. The interlayer dielectric film 115 has little effect of shielding hydrogen. On the other hand, in the present embodiment, the side surface of the barrier metal layer 60 is on substantially the same plane as the side surfaces of the upper electrode 50, the ferroelectric film 40, the lower electrode material 30, and the barrier metal layer 20, respectively. Therefore, the barrier metal layer 60 covers the whole upper surface of the upper electrode 50 with satisfactory coverage. Consequently, degradation of the ferroelectric film 40 is suppressed.

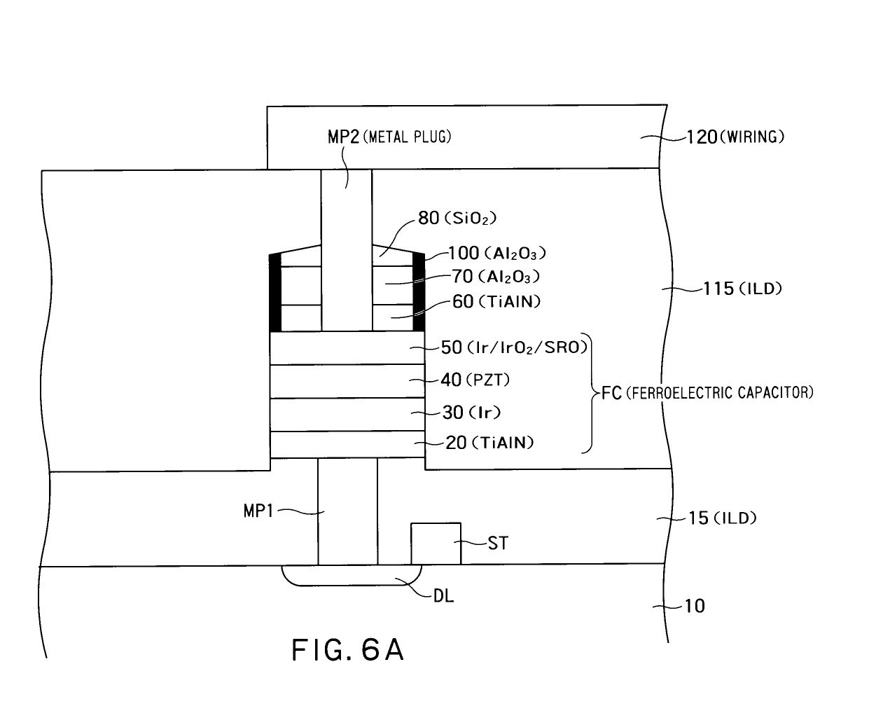

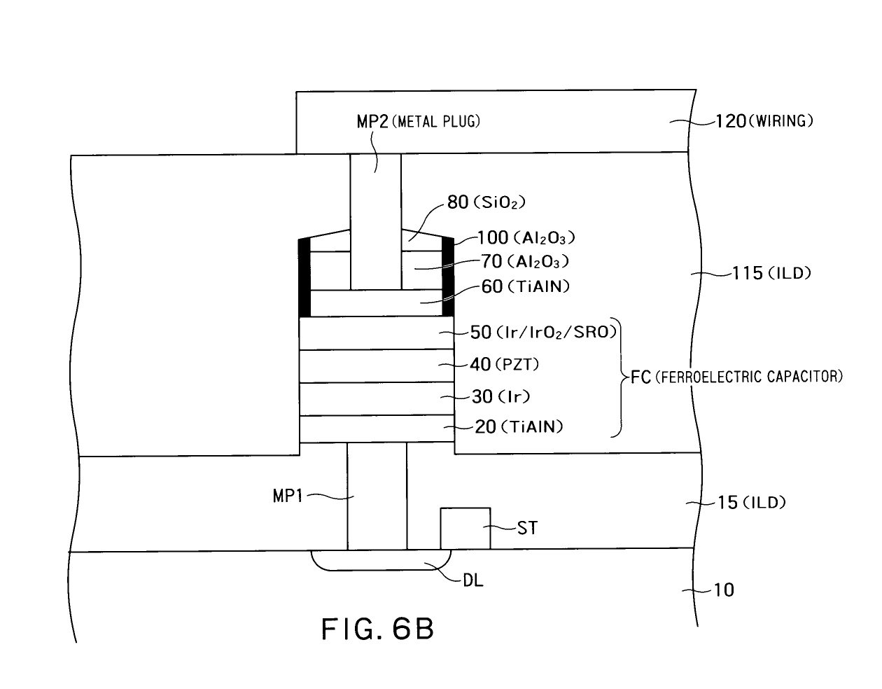

Next, as shown in FIG. 6A, a wiring 120 and others are formed on the interlayer dielectric film 115 including the metal plug MP2, thereby completing a ferroelectric memory according to the present embodiment. Alternatively, as shown in FIG. 6B, a contact hole used for the metal plug MP2 can be formed to pierce through only the interlayer dielectric film 115, the silicon oxide film 80, and the alumina layer 70, without piercing through the barrier metal 60. Accordingly, the metal plug MP2 can be formed to be in contact with the upper surface of the barrier metal 60.

According to the manufacturing method of the present embodiment, the side mask 100 suppresses the side etching of the barrier metal layer 60, in the etching process of the upper electrode material 50, the ferroelectric material 40, the lower electrode material 30, and the barrier metal layer 20. As a result, the barrier metal layer 60 covers the total upper surface of the upper electrode 50 with satisfactory coverage, and suppresses the entering of hydrogen into the contact portion on the upper electrode, thereby suppressing degradation of the ferroelectric film 40 by hydrogen.

The ferroelectric memory formed by the manufacturing method according to the present embodiment includes a switching transistor ST provided on the silicon substrate 10, the interlayer dielectric film 115 formed on the switching transistor ST, a ferroelectric capacitor FC, the upper electrode 50, the ferroelectric film 40, and the lower electrode 30 formed on the interlayer dielectric film 115, a metal plug MP1 provided within the interlayer dielectric film 115, and connected to the lower electrode 30, a diffusion layer DL connecting between the metal plug MP1 and the switching transistor ST, the barrier metal layer 60 provided on the upper electrode 50, and the side mask 100 provided on the side surface of the barrier metal layer 60 and having a side surface on the same plane as the side surface of the upper electrode, the side mask 100 shielding a gas for etching the ferroelectric material 40.

According to the present embodiment, the barrier metal layer 60 is not side etched. Therefore, the barrier metal layer 60 covers the whole upper surface of the upper electrode 50. As a result, degradation of the ferroelectric film 40 due to hydrogen can be suppressed.

Further, in the present embodiment, after the lower electrode material 30, the ferroelectric material 40, and the upper electrode material 50 are deposited, the barrier metal layer 60 is deposited on the upper electrode material 50. Thereafter, the barrier metal layer 60, the upper electrode material 50, the ferroelectric material 40, and the lower electrode material 30 are processed into the shape of a capacitor. The barrier metal layer 60 according to this method has a more satisfactory coverage on the upper surface of the upper electrode material 50 than the barrier metal according to the method described in the background technique. Therefore, the barrier metal layer 60 according to the present embodiment can shield hydrogen more satisfactorily than the conventional barrier metal layer.

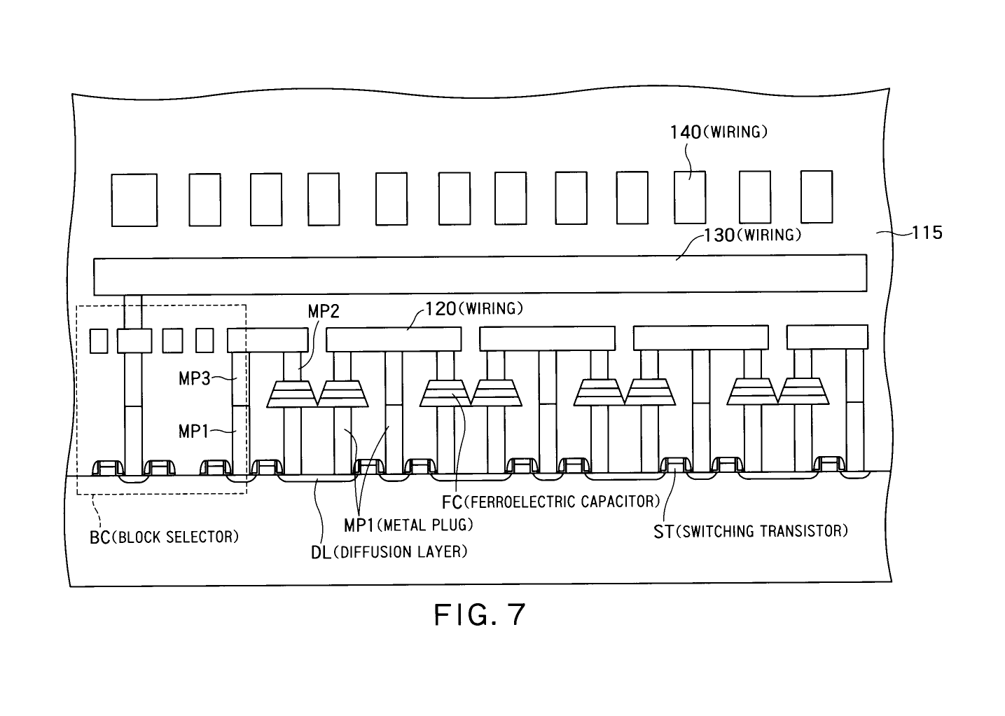

FIG. 7 is a cross-sectional view showing one example of the ferroelectric memory according to the first embodiment. FIG. 7 shows a “Series connected TC unit type ferroelectric RAM”, having both ends of a capacitor (C) connected to between a source and a drain of a cell transistor (T), as a unit cell, and having plural unit cells connected in series. The present embodiment can be of course applied to an optional memory having a ferroelectric capacitor, not only to the Series connected TC unit type ferroelectric RAM.

In FIG. 6A and FIG. 6B, the side surface of the ferroelectric capacitor FC is substantially perpendicularly etched. However, the side surface is actually formed in a sequentially tapered shape as shown in FIG. 7. In FIG. 7, the side mask 100, the silicon oxide film 80, the alumina layer 70, and the barrier metal layer 60 are omitted. In the example shown in FIG. 7, after the metal plug MP2 is formed, a metal plug MP3 is formed, and then, wirings 120, 130, 140 are formed.

### Second Embodiment

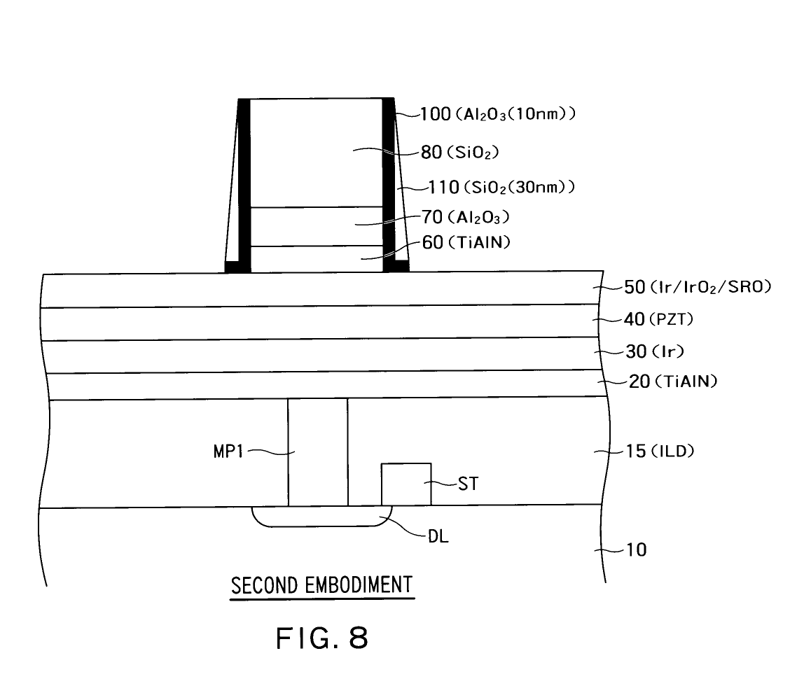

FIG. 8 is a cross-sectional view showing a manufacturing method of a ferroelectric memory according to a second embodiment of the present invention. The second embodiment is different from the first embodiment in that a laminated film of the alumina layer 100 (hereinafter, also “the alumina film 100”) and a silicon oxide film 110 are employed as the side mask 100. Other configurations of the second embodiment can be similar to those of the first embodiment.

After the alumina film 100 shown in FIG. 3 is deposited, the silicon oxide film 110 is deposited on the alumina film 100 by the CVD method or the like. By anisotropically etching the silicon oxide film 110 and the alumina film 100, the silicon oxide film 110 and the alumina film 100 are formed as a side mask on the side surface of the silicon oxide film 80, the alumina layer 70, and the barrier layer 60, respectively. The alumina film 100 has a film thickness of 10 nm, for example. The silicon oxide film 110 has a deposition film thickness of 30 nm, for example.

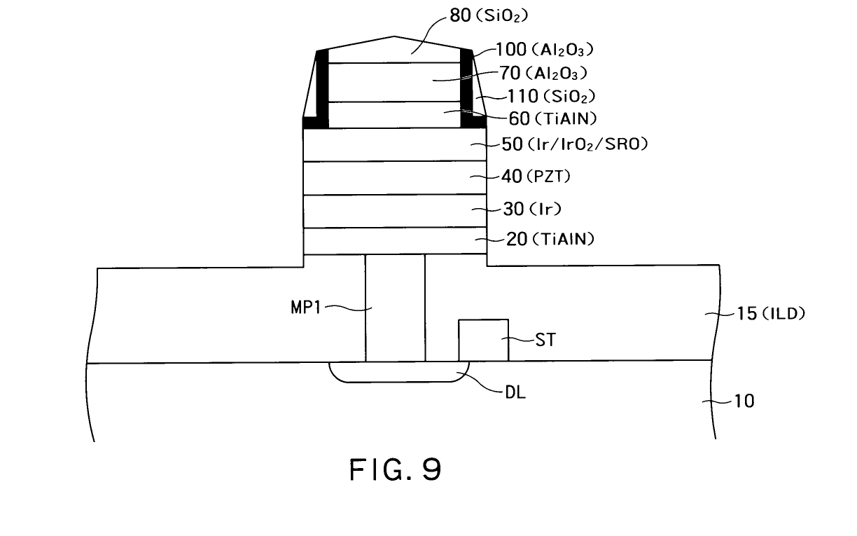

Next, as shown in FIG. 9, the upper electrode material 50, the ferroelectric material 40, the lower electrode material 30, and the barrier metal layer 20 are anisotropically etched by using the silicon oxide films 80, 110, and the alumina layer 100 as a mask. Accordingly, the upper electrode material 50, the ferroelectric material 40, and the lower electrode material 30 are obtained. Thereafter, the ferroelectric memory is completed through a process similar to that of the first embodiment.

Like in the second embodiment, the side mask can be a laminated film. Effects similar to those of the first embodiment can be obtained from the second embodiment.

### Third Embodiment

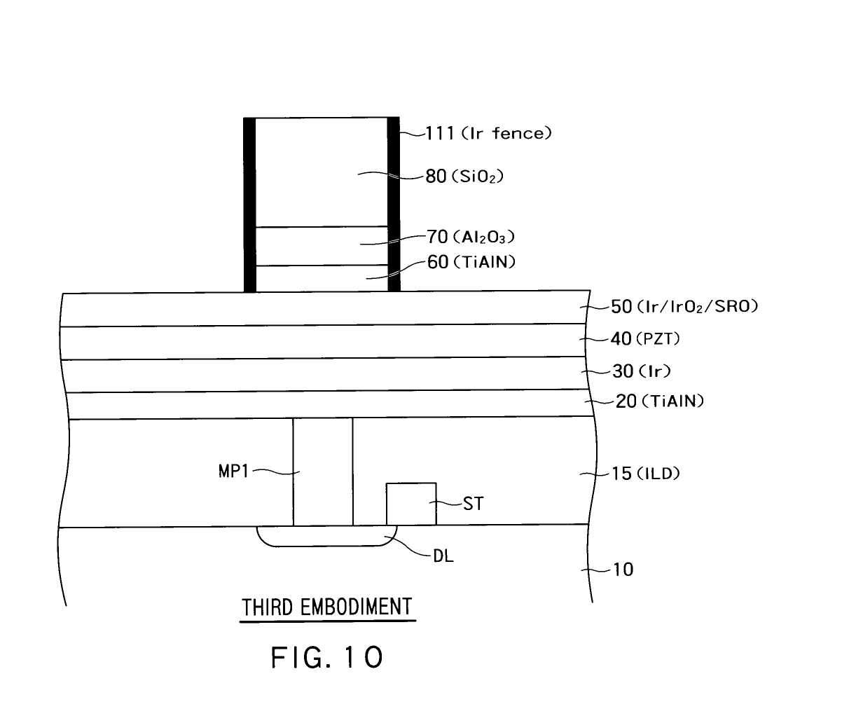

FIG. 10 is a cross-sectional view showing a manufacturing method of a ferroelectric memory according to a third embodiment of the present invention. The third embodiment is different from the first embodiment in that iridium as the same material as that of the upper layer of the upper electrode 50 is employed as a side mask. Other configurations of the third embodiment can be similar to those of the first embodiment.

In the third embodiment, a part of the upper electrode material 50 is further over-etched in the etching process of the barrier metal layer 60 shown in FIG. 2. Because the upper layer of the upper electrode material 50 is formed by iridium, the etched iridium is deposited as an iridium layer 111 on the side surface of the silicon oxide film 80, the alumina layer 70, and the barrier metal layer 60.

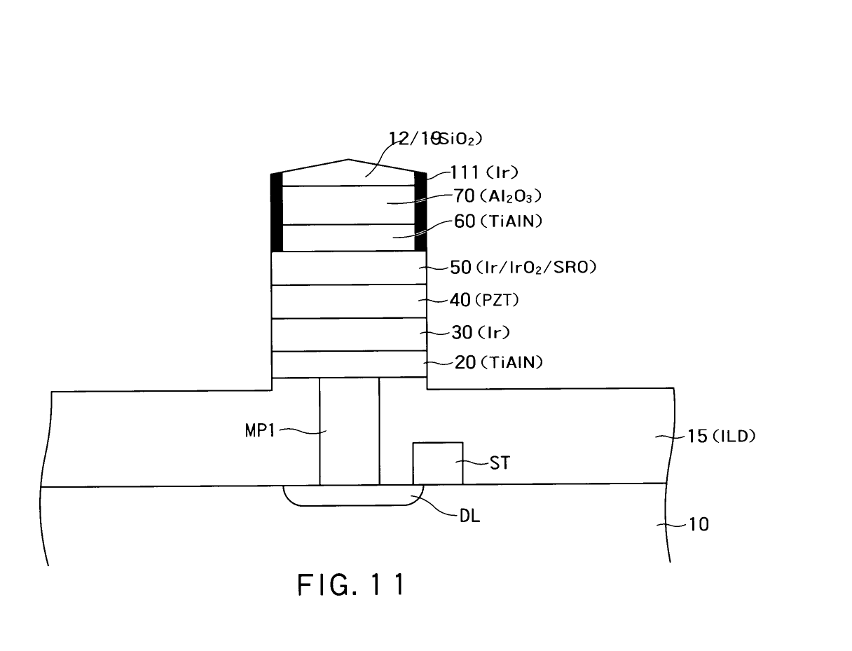

Next, as shown in FIG. 11, the upper electrode material 50, the ferroelectric material 40, the lower electrode material 30, and the barrier metal layer 20 are anisotropically etched by using the silicon oxide film 80 and the iridium layer 111 as a mask. As a result, the upper electrode 50, the ferroelectric film 40, and the lower electrode 30 are obtained. Thereafter, in the same process as that of the first embodiment, the ferroelectric memory is completed. The manufacturing method according to the third embodiment is simpler than the manufacturing method according to the first embodiment, because the side mask (the iridium layer 111) is formed simultaneously with the etching of the barrier metal layer 60. Further, effects similar to those of the first embodiment can be obtained from the third embodiment.

### Fourth Embodiment

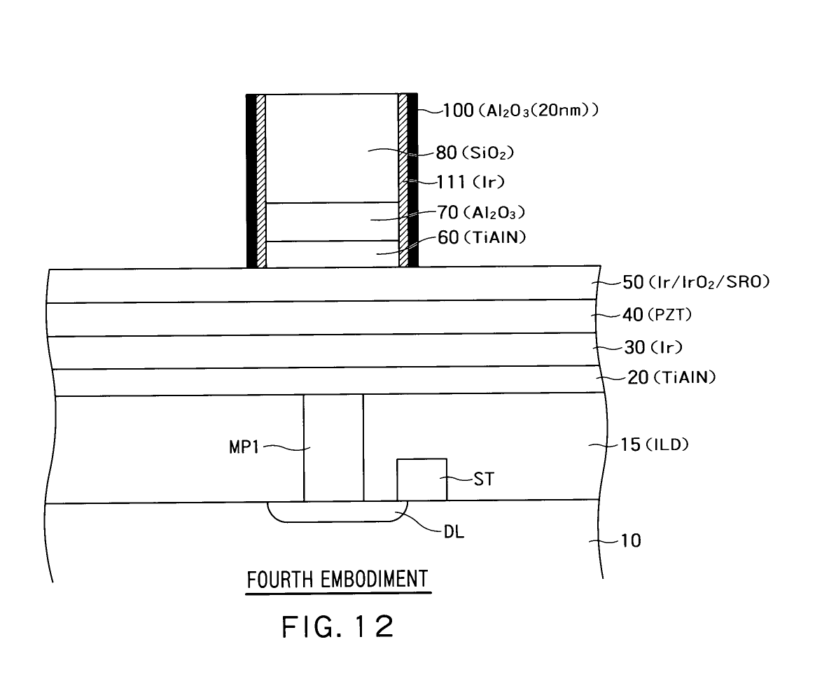

FIG. 12 is a cross-sectional view showing a manufacturing method of a ferroelectric memory according to a fourth embodiment of the present invention. The fourth embodiment is different from the first embodiment in that a laminated film including the iridium layer 111 and the alumina layer 100 is employed as a side mask. Other configurations of the fourth embodiment can be similar to those of the first embodiment. The iridium layer 111 is provided nearer to the side surface of the barrier metal layer 60 than the alumina layer 100.

In the fourth embodiment, a part of the upper electrode material 50 is further over-etched in the etching process of the barrier metal layer 60 shown in FIG. 2. Because the upper layer of the upper electrode material 50 is formed by iridium, the etched iridium is deposited as the iridium layer 111 on the side surface of the silicon oxide film 80, the alumina layer 70, and the barrier metal layer 60.

After the alumina film 100 is deposited, the alumina film 100 is anisotropically etched. As a result, the alumina film 100 and the iridium layer 111 are formed as a side mask, on the side surface of the silicon oxide film 80, the alumina layer 70, and the barrier metal layer 60, respectively.

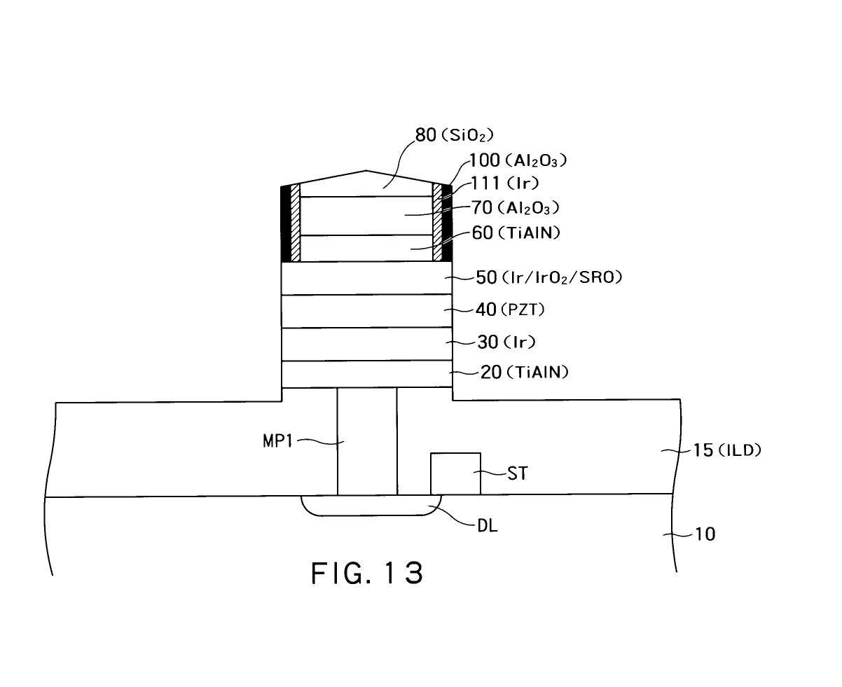

Next, as shown in FIG. 13, the upper electrode material 50, the ferroelectric material 40, the lower electrode material 30, and the barrier metal layer 20 are anisotropically etched by using the silicon oxide film 80, the alumina layer 100, and the iridium layer 111 as a mask. As a result, the upper electrode material 50, the ferroelectric film 40, and the lower electrode film 30 are obtained. Thereafter, the ferroelectric memory is completed through a similar process to that of the first embodiment. The manufacturing method according to the fourth embodiment uses a laminated film of the iridium layer 111 and the alumina layer 100 as a side mask. Therefore, side etching of the barrier metal layer 60 can be more securely suppressed. Further, effects similar to those of the first embodiment can be obtained from the fourth embodiment.

### Fifth Embodiment

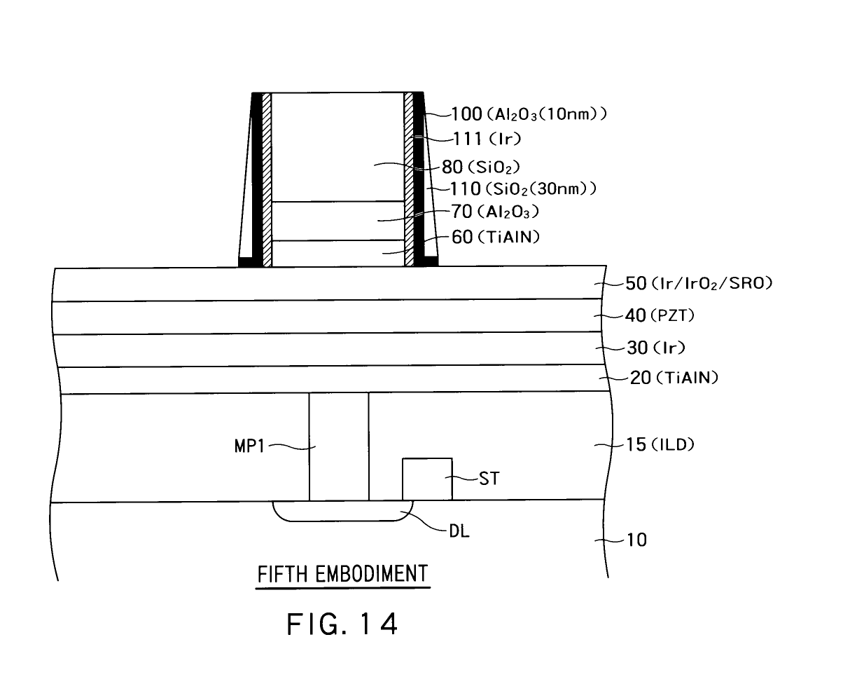

FIG. 14 is a cross-sectional view showing a manufacturing method of a ferroelectric memory according to a fifth embodiment of the present invention. The fifth embodiment is different from the first embodiment in that a three-layer film including the iridium layer 111, the alumina layer 100, and the silicon oxide film 110 is employed as a side mask. Other configurations of the fifth embodiment can be similar to those of the first embodiment. The iridium layer 111 out of the three-layer film is nearest to the side surface of the barrier metal layer 60.

In the fifth embodiment, a part of the upper electrode material 50 is further over-etched in the etching process of the barrier metal layer 60 shown in FIG. 2. Because the upper layer of the upper electrode material 50 is formed by iridium, the etched iridium is deposited as the iridium layer 111 on the side surface of the silicon oxide film 80, the alumina layer 70, and the barrier metal layer 60.

After the alumina film 100 is deposited, the silicon oxide film 110 is deposited on the alumina film 100. By anisotropically etching the silicon oxide film 110 and the alumina film 100, the silicon oxide film 110 and the alumina film 100 are formed as a side mask, on the side surface of the silicon oxide film 80, the alumina layer 70, and the barrier metal layer 60, respectively.

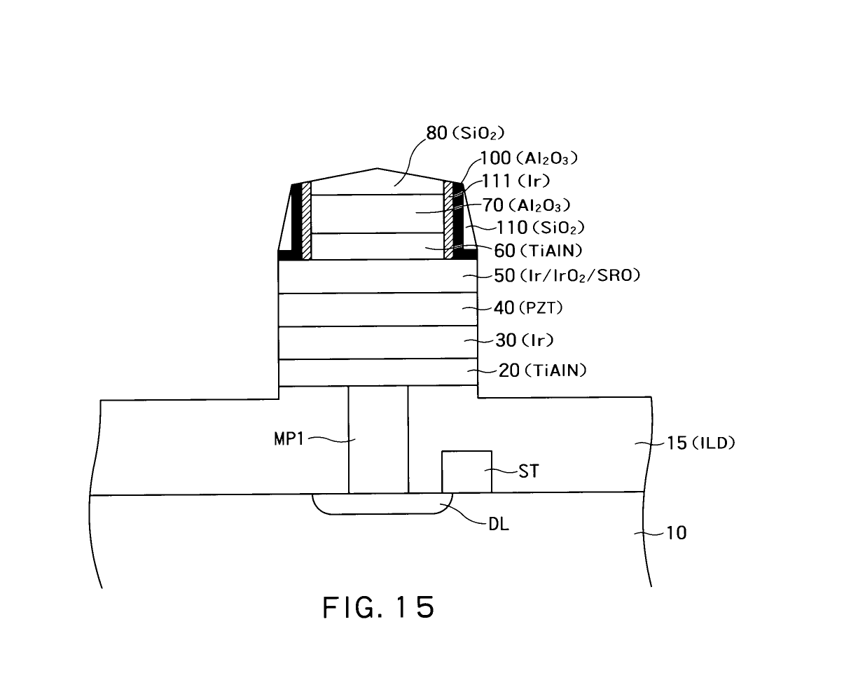

Next, as shown in FIG. 15, the upper electrode material 50, the ferroelectric material 40, the lower electrode material 30, and the barrier metal layer 20 are anisotropically etched by using the silicon oxide films 80, 110, the alumina layer 100, and the iridium layer 111 as a mask. As a result, the upper electrode 50, the ferroelectric film 40, and the lower electrode 30 are obtained. Thereafter, the ferroelectric memory is completed through a similar process to that of the first embodiment. The manufacturing method according to the fifth embodiment uses a three-layer film of the iridium layer 111, the alumina layer 100, and the silicon oxide film 110 as a side mask. Therefore, side etching of the barrier metal layer 60 can be more securely suppressed. Further, effects similar to those of the first embodiment can be obtained from the fifth embodiment.

### Sixth Embodiment

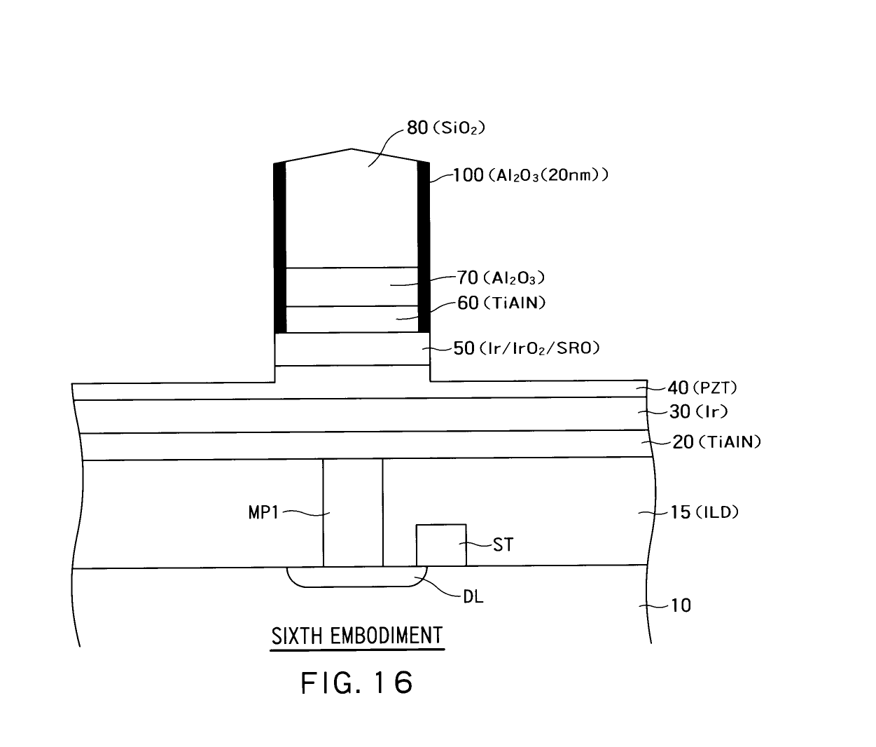

FIG. 16 is a cross-sectional view showing a manufacturing method of a ferroelectric memory according to a sixth embodiment of the present invention. In the sixth embodiment, etching of the ferroelectric material 40 is once stopped, and a second side mask is formed on the upper side surface of the upper electrode 50 and the ferroelectric material 40. Thereafter, etching of the ferroelectric material 40 is continued again. Other configurations of the sixth embodiment can be similar to those of the first embodiment.

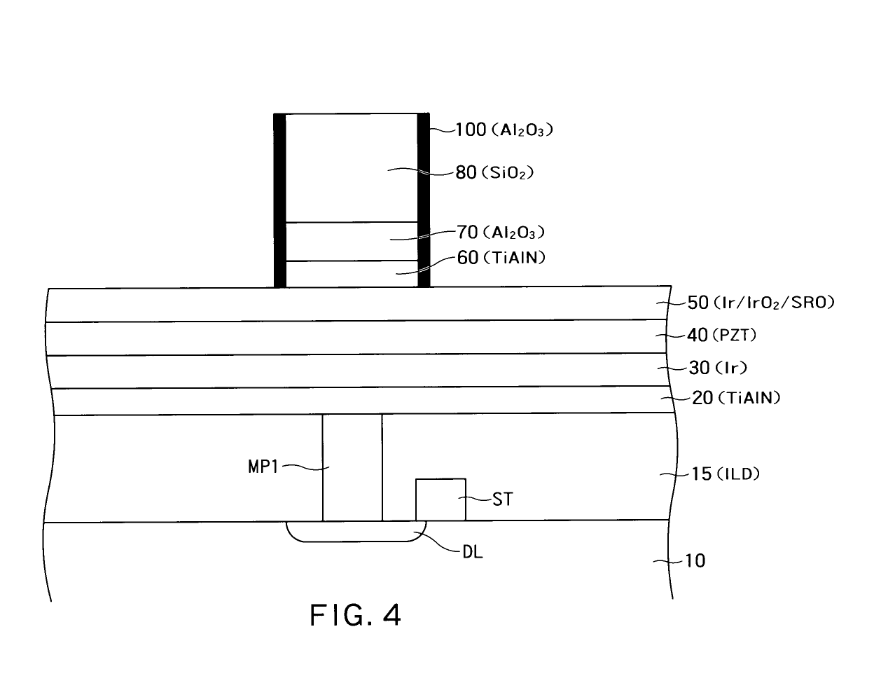

As shown in FIG. 4, the alumina film 100 as a first side mask is formed. Next, the upper part of the upper electrode material 50 and the ferroelectric material 40 is anisotropically etched by RIE by using the silicon oxide films 80, the alumina layer 70, and the side mask 100 as a mask. As a result, a structure as shown in FIG. 16 is obtained.

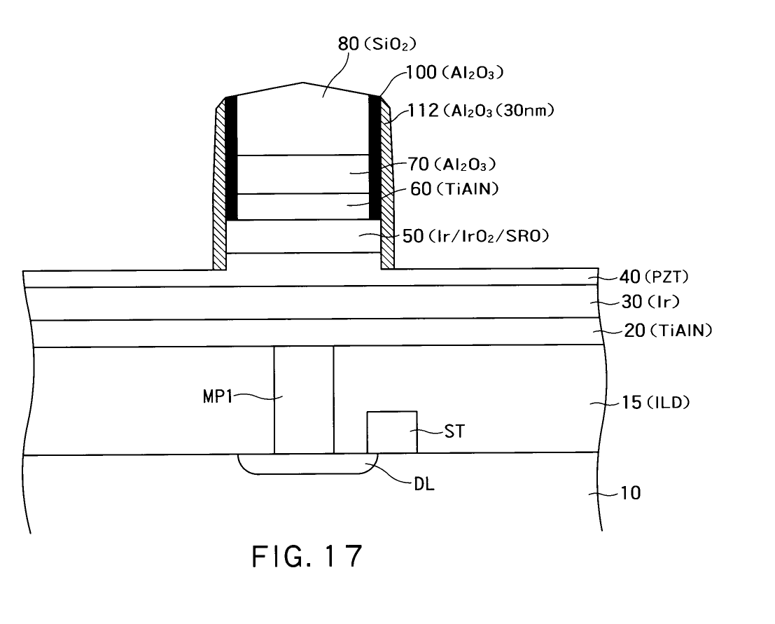

An alumina film 112 is deposited on the upper surface of the ferroelectric material 40, on the side surface of the upper part of the ferroelectric material 40, on the side surface of the upper electrode 50, on the front surface of the alumina film 100, and the upper surface of the silicon oxide film 80, and the alumina film 112 is anisotropically etched back. As a result, as shown in FIG. 17, the alumina film 112 as a second side mask is formed on the, on the side surface of the upper part of the ferroelectric material 40, on the side surface of the upper electrode 50, and on the top surface of the alumina film 100. The alumina film 112 has a film thickness of 30 nm, for example. The alumina film 112 is deposited by the ALD method, for example.

The second side mask is preferably a single layer film of aluminum oxide (Al₂O₃, etc.), zirconium oxide (ZrO₂, etc.), aluminum silicon oxide (AlSiₓO_{y}, etc.), silicon oxide (SiO₂), titan oxide (TiO₂, etc.), silicon nitride (Si₃N₄, etc.), aluminum nitride (AlN) or aluminum oxynitride (AlOₓN_{y}), or a laminated film of two or more layers of these materials. This is because these materials are excellent in shielding of hydrogen.

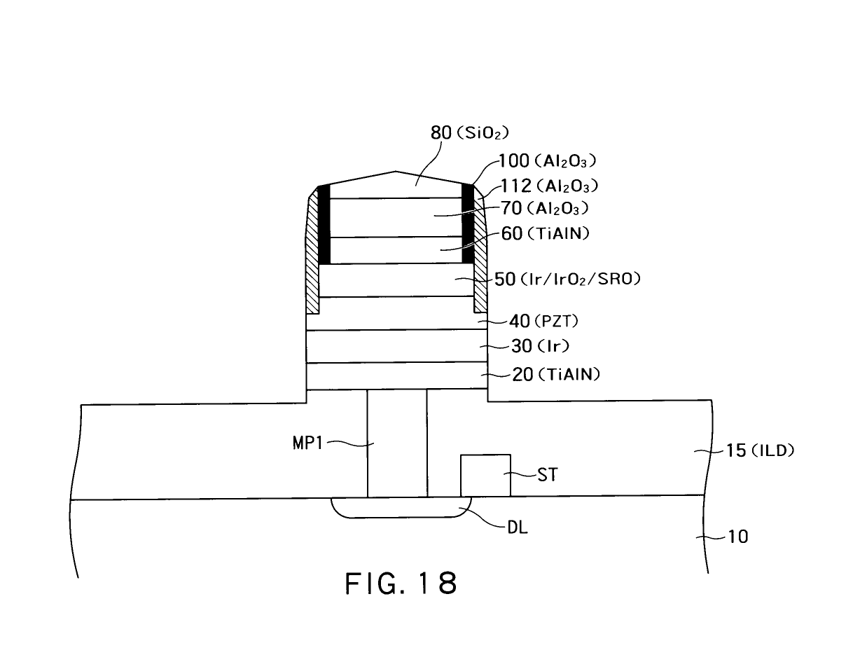

Thereafter, as shown in FIG. 18, the lower part of the ferroelectric material 40, the lower electrode material 30, and the barrier metal layer 20 are anisotropically etched by using the alumina film 100 (a first side mask), the alumina film 112 (a second side mask), and the silicon oxide film 80 as a mask. Further, through the process similar to that of the first embodiment, the ferroelectric memory is completed. The side surface of the upper electrode 50 and the side surface of the lower electrode are on different plane surfaces.

According to the sixth embodiment, at the time of etching the lower part of the ferroelectric material 40, the alumina film 112 covers the interface between the ferroelectric material 40 and the upper electrode 50. As a result, a gas containing chlorine used to etch the ferroelectric material 40 can be suppressed from being diffused to the barrier layer 60 from the interface between the ferroelectric material 40 and the upper electrode 50. Accordingly, in the sixth embodiment, etching of the barrier metal layer 60 by the gas containing chlorine can be suppressed more than in the first embodiment.

In the sixth embodiment, the single layer film or the laminated film used in the second to the fifth embodiments can be employed in place of the alumina film 100, for the first side mask. In this case, the effects of any one of the second to the fifth embodiments can be obtained from the sixth embodiment.

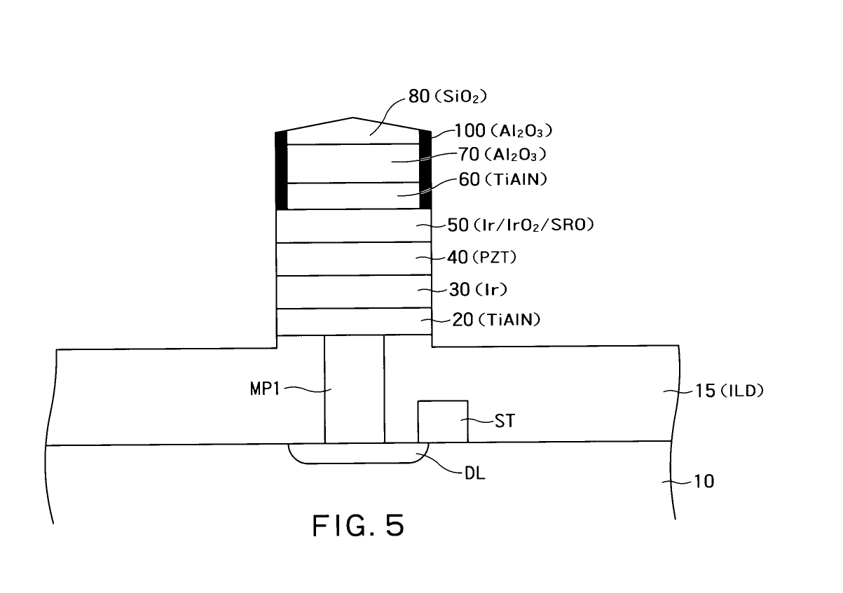

Either a part or whole of the silicon oxide film 80, the alumina film 70, and the barrier metal layer 60 shown in FIG. 5, FIG. 9, FIG. 11, FIG. 13, FIG. 15, and FIG. 18 in the first to the sixth embodiments do not need to remain at the completion time of the ferroelectric memory. For example, after the ferroelectric capacitor FC is processed, the silicon oxide film 80 can be removed, and the alumina film 70 and the barrier metal layer 60 can remain. After the ferroelectric capacitor FC is processed, the silicon oxide film 80 and the alumina film 70 can be removed, and the barrier metal layer 60 can remain. Alternatively, after the ferroelectric capacitor FC is processed, all the silicon oxide film 80, the alumina film 70, and the barrier metal layer 60 can be removed.

In the first to the sixth embodiments, the barrier metal layer 60 and the side masks 100, 110, and 111 can shield not only the hydrogen gas in the CVD in the deposition process of tungsten but also the hydrogen in other processes and hydrogen entering after the manufacturing.

1. A semiconductor device comprising:
a switching transistor provided on a semiconductor substrate;
an interlayer dielectric film formed on the switching transistor;
a ferroelectric capacitor including an upper electrode, a ferroelectric film, and a lower electrode formed on the interlayer dielectric film;
a contact plug provided within the interlayer dielectric film and electrically connected to the lower electrode;
a diffusion layer connected to between the contact plug and the switching transistor;
a barrier metal covering a whole upper surface of the upper electrode; and
an insulation sidewall film provided on a side surface of the barrier metal and provided substantially on a same plane as a side surface of the upper electrode.

2. The semiconductor device according to claim 1, wherein the insulation sidewall film is a laminated film including a plurality of materials laminated on the side surface of the barrier metal.

3. The semiconductor device according to claim 2, wherein a layer nearest to the side surface of the barrier metal among layers forming the laminated film is formed by a same material as that of the upper electrode.

4. The semiconductor device according to claim 1, wherein the insulation sidewall film is a single layer film including aluminum oxide, zirconium oxide, aluminum silicon oxide, silicon oxide, titan oxide, silicon nitride, aluminum nitride, or aluminum oxynitride, or a laminated film of two or more layers of these materials.

5. The semiconductor device according to claim 1, further comprising:
a first layer provided between the insulation sidewall film and the side surface of the barrier metal, and formed by a same material as a material of an upper part of the upper electrode.

6. The semiconductor device according to claim 1, further comprising:
a first layer provided between the insulation sidewall film and the side surface of the barrier metal, and including a same material as a material of an upper part of the upper electrode; and
a second layer provided on the side surface of the barrier metal via the insulation sidewall film and the first layer.

7. The semiconductor device according to claim 1, wherein side surfaces of the upper electrode, the ferroelectric film and the lower electrode respectively are substantially on a same plane.

8. The semiconductor device according to claim 1, wherein side surfaces of the upper electrode and the lower electrode respectively are on different planes each other.

9. The semiconductor device according to claim 1, wherein the barrier metal is a single layer film of titan nitride, titan aluminum nitride, tungsten nitride or titanium, or a laminated film of these materials.

10. The semiconductor device according to claim 1, further comprising:
a hard mask provided on the barrier metal and formed by a single layer film of aluminum oxide, zirconium oxide, aluminum silicon oxide, silicon oxide, titan oxide, aluminum oxynitride or silicon nitride, or a laminated film of two or more layers of these materials.

11. The semiconductor device according to claim 1, wherein the upper electrode is a single layer film of Ir, oxide iridium, Pt, SrRuO₃, LaSrO₃ or SrRuO₃, or a laminated film of these materials.

12. The semiconductor device according to claim 1, wherein the lower electrode is a single layer film of Ir, oxide iridium, Pt, SrRuO₃, LaSrO₃ or SrRuO₃, or a laminated film of these materials.

13. The semiconductor device according to claim 1, further comprising:
a second barrier metal provide below the lower electrode and formed by a single layer film of titan nitride, titan aluminum nitride, tungsten nitride or titanium, or a laminated film of these materials.

14. The semiconductor device according to claim 1, wherein the ferroelectric material includes PZT (Pb (ZrₓTi₍₁₋ₓ₎O₃), SBT (SrₓBi_{y}Ta_{z}Oₐ), BLT (BiₓLa_{y}O_{z}), where x, y, z, a are positive numbers.

15. The semiconductor device according to claim 1, wherein the ferroelectric capacitor is used in a series connected TC unit type ferroelectric memory.

16. A manufacturing method of a semiconductor device including a ferroelectric capacitor including an upper electrode, a ferroelectric film, and a lower electrode, the manufacturing method comprising:
forming a switching transistor on a semiconductor substrate and a diffusion layer connected to the switching transistor;
forming an interlayer dielectric film on the switching transistor;
forming a contact plug connected to the diffusion layer within the interlayer dielectric film;
depositing a lower electrode material, a ferroelectric film material, and an upper electrode material on the contact plug;
depositing a barrier metal on the upper electrode;
depositing a mask material on the barrier metal;
processing the mask material into a pattern of the ferroelectric capacitor;
etching the barrier metal using the mask material as a mask;
forming an insulation sidewall film on a side surface of the barrier metal; and
etching the upper electrode material, the ferroelectric film material, and the lower electrode material by using the mask material and the insulation sidewall film as a mask to form the upper electrode, the ferroelectric film and the lower electrode.
